(19) United States
(12) Patent Application Publication
(10) Pub. No.: US 2026/0292984 A1
(43) Pub. Date: Sep. 24, 2026

(54) WIRING SUBSTRATE

(71) Applicant: NITERRA CO., LTD., Nagoya-shi (JP)

(72) Inventors: Junya MATSURA, Nagoya-shi (JP); Kota KIMATA, Nagoya-shi (JP)

(21) Appl. No.: 19/559,609

(22) Filed: Mar. 6, 2026

(30) Foreign Application Priority Data
Mar. 21, 2025 (JP) 2025-046410

(51) Int. Cl. H05K 1/11; H05K 1/03

(52) U.S. Cl. CPC H05K 1/115; H05K 1/0306; H05K 1/0353

(57) ABSTRACT

A wiring substrate includes a ceramic substrate having first and second main faces and having a first conductor trace formed on its first main face, and a resin layer having first and second main faces and stacked on the first main face of the ceramic substrate, on which the first conductor trace is formed. The resin layer has a second conductor trace formed on its second main face, different from its first main face facing the ceramic substrate. The resin layer has a plurality of vias having electrical conductivity and establishing connection between the first conductor trace and the second conductor trace. The vias penetrate the resin layer in a stacking direction in which the ceramic substrate and the resin layer are stacked.

### CROSS-REFERENCE TO RELATED APPLICATIONS

The present application claims priority from Japanese patent application No. 2025-046410 filed on Mar. 21, 2025, the entirety of the disclosure of which is incorporated herein by reference.

### BACKGROUND OF THE INVENTION

### 1. FIELD OF THE INVENTION

The present invention relates to a wiring substrate.

### 2. DESCRIPTION OF THE RELATED ART

There has been known a wiring substrate in which a plurality of resin layers are stacked on a ceramic substrate (see, for example, WO2015/102107). In the wiring substrate disclosed in WO2015/102107, electrical connection between a conductor trace formed on the ceramic substrate and a conductor trace formed on the resin layers stacked on the ceramic substrate is established by a via which penetrates the resin layers in a thickness direction.

### SUMMARY OF THE INVENTION

Almost no adhesion occurs between the conductor trace formed on the ceramic substrate and the via penetrating the resin layers. Therefore, connection between the conductor trace and the via is established as a result of fusion of the ceramic substrate-side surface of the resin layer (located adjacent to the ceramic substrate) to the ceramic substrate. However, in the case where the resin layer and the ceramic substrate are not sufficiently brought into close contact with each other, it may be the case that the conductor trace and the via are not connected. If the conductor trace and the via are not connected, a connection failure occurs. Although WO2015/102107 discloses a technique for suppressing shrinkage of the wiring substrate by forming a dummy conductor trace on the resin layers, the connection failure between the conductor trace on the ceramic substrate and the via penetrating the resin layers is not considered.

The present invention has been accomplished so as to solve at least partially the above-described problem, and an object of the present invention is to provide a technique for a wiring substrate including a ceramic substrate and a resin layer stacked on the ceramic substrate, the technique suppressing occurrence of a connection failure between a conductor trace formed on the ceramic substrate and a via penetrating the resin layer.

The present invention can be realized as the following aspect.

(1) According to one aspect of the present invention, a wiring substrate is provided. The wiring substrate includes: a ceramic substrate having first and second main faces and having a first conductor trace formed on its first main face; a resin layer having first and second main faces and stacked on the first main face of the ceramic substrate, on which the first conductor trace is formed, the resin layer having a second conductor trace formed on its second main face, different from its first main face facing the ceramic substrate. In the wiring substrate, the resin layer has a plurality of vias which have electrical conductivity and establish connection between the first conductor trace and the second conductor trace, the vias penetrating the resin layer in a stacking direction in which the ceramic substrate and the resin layer are stacked.

By virtue of this configuration, the first conductor trace formed on the first main face of the ceramic substrate and the second conductor trace formed on the resin layer stacked on the first main face of the ceramic substrate are connected to each other by a plurality of vias. The first conductor trace and the second conductor trace are connected not by a single via but by the plurality of vias. Therefore, even when some of the plurality of vias suffer connection failures, the connection between the first conductor trace and the second conductor trace is secured by the remaining via(s). Namely, since the plurality of vias are present, it is possible to increase the probability of securing the electrical conduction between the first conductor trace and the second conductor trace, thereby suppressing occurrence of a connection failure.

(2) In the wiring substrate of the above-described aspect, a number of the vias for establishing connection between the first conductor trace and the second conductor trace may be three or more.

By virtue of this configuration, three or more vias (i.e., many vias) are provided. Therefore, the area of joining between the first conductor trace and the three or more vias and the area of joining between the second conductor trace and the three or more vias increase. Thus, occurrence of a connection failure between the first conductor trace and the second conductor trace is suppressed further.

(3) In the wiring substrate of the above-described aspect, a sum of areas of joining between the plurality of vias and the first conductor trace may be larger than a sum of areas of joining between the plurality of vias and the second conductor trace.

By virtue of this configuration, in the case where a resin stacked body composed of a plurality of resin layers is stacked on a ceramic substrate, the area of joining between the vias formed in the resin stacked body and the first conductor trace formed on the first main face of the ceramic substrate increases. Therefore, it is possible to further suppress occurrence of a joining failure between the first conductor trace and the vias, which joining failure is more likely to occur as compared with a joining failure between the second conductor trace and the vias.

The present invention can be realized in various aspects. For example, the present invention can be realized, for example, as a wiring substrate, an electronic component, a system including the wiring substrate and/or the electronic component, a method for manufacturing the wiring substrate, or a method for manufacturing the system including the wiring substrate and/or the electronic component.

### BRIEF DESCRIPTION OF THE DRAWINGS

FIG. 1 is a schematic sectional view of a wiring substrate according to one embodiment of the present invention;

FIGS. 2(a) and 2(b) are schematic sectional views of a ceramic substrate and a resin stacked body of the embodiment before the ceramic substrate and the resin stacked body are joined together and after the ceramic substrate and the resin stacked body have been joined together;

FIGS. 3(a) and 3(b) are schematic sectional views of a ceramic substrate and a resin stacked body of a comparative example before the ceramic substrate and the resin stacked body are joined together and after the ceramic substrate and the resin stacked body have been joined together;

FIG. 4 is a schematic sectional view of a wiring substrate of a second embodiment; and

FIG. 5 is a schematic sectional view of a wiring substrate of a modification.

### DESCRIPTION OF THE PREFERRED EMBODIMENT

### FIRST EMBODIMENT

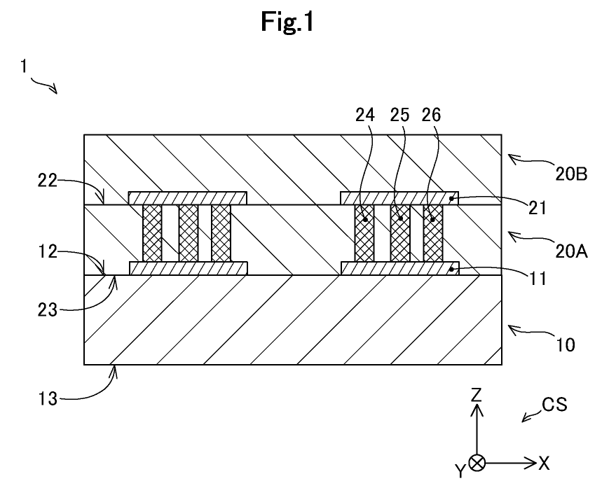

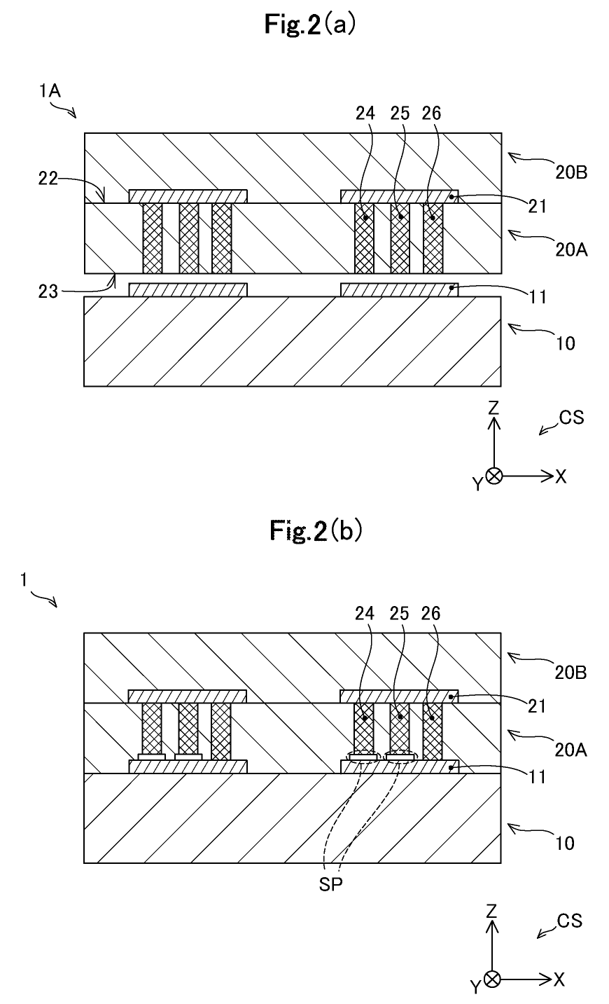

FIG. 1 is a schematic sectional view of a wiring substrate 1 according to one embodiment of the present invention. The wiring substrate 1 of the present embodiment is used for circuit formation of an electronic component, an IC package, a sensor device, a semiconductor manufacturing apparatus, or the like. As shown in FIG. 1, the wiring substrate 1 includes a ceramic substrate 10 having a pair of main faces (hereinafter referred to as first and second main faces) 12 and 13, and a plurality of resin layers 20A and 20B stacked on the first main face 12 of the ceramic substrate 10. The ceramic substrate 10 is mainly formed of a ceramic material such as alumina. The resin layers 20A and 20B are formed of a resin material such as polyimide. Notably, in FIG. 1, of the plurality of resin layers, two resin layers 20A and 20B are shown, and other resin layers are not shown. A cartesian coordinate system CS shown in FIG. 1 has an X axis and a Y axis, which are orthogonal to a Z-axis direction corresponding to a stacking direction in which the ceramic substrate 10 and the resin layers 20A and 20B are stacked. The cartesian coordinate system CS shown in FIG. 1 corresponds to the cartesian coordinate systems CS shown in FIGS. 2(a) and 2(b), 3(a) and 3(b), 4, and 5.

As shown in FIG. 1, a first conductor trace 11 having electrical conductivity is formed on the first main face 12 of the ceramic substrate 10. The first conductor trace 11 is formed by applying a metal material containing, for example, copper as a main component to the ceramic substrate 10 as a paste and performing firing, or by plating the ceramic substrate 10 with the metal material. One main face (hereinafter referred to as a first main face) 23 of the resin layer 20A is joined to the first main face 12 of the ceramic substrate 10. In a heated state, the first main face 23 of the resin layer 20A is joined to the first main face 12 of the ceramic substrate 10. As a result, the resin layer 20A is stacked on the first main face 12 of the ceramic substrate 10. A second conductor trace 21 having electrical conductivity is formed on the other main face (hereinafter referred to as a second main face) 22 of the resin layer 20A, which main face is not joined to the ceramic substrate 10. The second conductor trace 21 is formed on the resin layer 20A at a position which faces the first conductor trace 11 when the resin layer 20A is stacked on the ceramic substrate 10. The second conductor trace 21 is formed by applying a metal material, as metal foil, to the resin layer 20A by means of fusion, or by plating the resin layer 20A with the metal material. The metal material contains, as a main component, copper, aluminum, silver, gold, platinum, nickel, titanium, iron, chromium, molybdenum, tungsten, or the like.

As shown in FIG. 1, the resin layer 20A has three vias 24 to 26, which penetrate the resin layer 20A in the stacking direction. The three vias 24 to 26 are formed by filling through holes formed in the resin layer 20A with an electrically conductive paste containing copper or silver as a main component, followed by firing. Since the vias 24 to 26 have electrical conductivity, the vias 24 to 26 electrically connect the first conductor trace 11 on the ceramic substrate 10 and the second conductor trace 21 on the resin layer 20A. Notably, in the present embodiment, cross sections of the vias 24 to 26 perpendicular to the stacking direction are circular and have a diameter of 30 micrometers.

FIGS. 2(a) and 2(b) are views used for describing a joining failure between the first conductor trace 11 and the vias 24 to 26. FIGS. 2(a) and 2(b) show schematic cross sections of the ceramic substrate 10 and a resin stacked body 1A, in which a plurality of resin layers, including the two resin layers 20A and 20B, are stacked. Specifically, FIG. 2(a) shows a state before the resin stacked body 1A and the ceramic substrate 10 are joined together, and FIG. 2(b) shows a state after the resin stacked body 1A and the ceramic substrate 10 have been joined together. As shown in FIG. 2(a), the second conductor trace 21 is formed on the second main face 22 of the resin layer 20A contained in the resin stacked body 1A, and the three vias 24 to 26 are formed in the resin layer 20A.

In the pre-joining state shown in FIG. 2(a), the resin stacked body 1A is heated, and the resin stacked body 1A is stacked on the ceramic substrate 10. When the resin stacked body 1A is heated, a portion of the resin layer 20A on the first main face 23 side functions as an adhesive for joining the resin layer 20A to the ceramic substrate 10. After joining, as shown in FIG. 2(b), a gap(s) SP may be formed between some of the three vias 24 to 26 and the first conductor trace 11 in some cases. Specifically, gaps SP may be formed between the first conductor trace 11 and ends of some vias 24 and 25 on the ceramic substrate 10 side. In this case, the vias 24 and 25 are not joined to the first conductor trace 11. Meanwhile, the via 26 and the first conductor trace 11, between which the gap SP is not formed, are joined to each other. Although the first main face 23 of the heated resin layer 20A functions as an adhesive, no adhesion occurs between the vias 24 to 26 and the first conductor trace 11. Therefore, in the case where the degree of close contact between the resin layer 20A and the ceramic substrate 10 is not sufficiently high, as shown in FIG. 2(b), joining failures occur between some vias 24 and 25 and the first conductor trace 11. In the present embodiment, the three vias 24 to 26 are formed in the resin layer 20A. Therefore, even when some vias 24 and 25 surfer joining failures, no connection failure occurs between the first conductor trace 11 and the second conductor trace 21, because the remaining via 26 is joined to the first conductor trace 11.

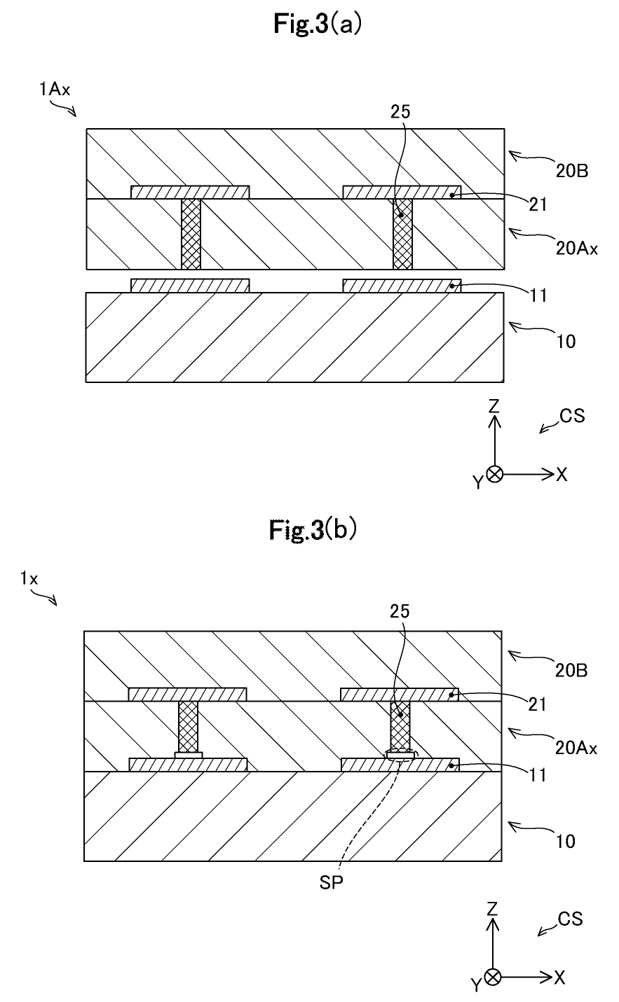

FIGS. 3(a) and 3(b) are views used for describing a joining failure between a first conductor trace 11 and a via 25 of a comparative example. FIGS. 3(a) and 3(b) show schematic cross sections of a resin stacked body 1Ax of the comparative example and the ceramic substrate 10. Specifically, FIG. 3(a) shows a state before the resin stacked body 1Ax and the ceramic substrate 10 are joined together, and FIG. 3(b) shows a state after the resin stacked body 1Ax and the ceramic substrate 10 have been joined together. Unlike the first embodiment shown in FIGS. 1 and 2(a) and 2(b), in the comparative example, the first conductor trace 11 and the second conductor trace 12 are connected by the single via 25. Therefore, if a joining failure occurs between the via 25 and the first conductor trace 11 as shown in FIG. 3(b), it becomes impossible to ensure the electrical conduction between the first conductor trace 11 and the second conductor trace 21.

As described above, in the wiring substrate 1 of the present embodiment, the resin layer 20A has the plurality of vias 24 to 26 penetrating the resin layer 20A in the stacking direction. Since the vias 24 to 26 have electrical conductivity, the vias 24 to 26 establish electrical connection between the first conductor trace 11 formed on the first main face 12 of the ceramic substrate 10 and the second conductor trace 21 formed on the second main face 22 of the resin layer 20A. In the present embodiment, the first conductor trace 11 and the second conductor trace 21 are connected not by a single via but by the plurality of vias 24 to 26. Therefore, even when, of the vias 24 to 26, some vias 24 and 25 surfer connection failures, the connection between the first conductor trace 11 and the second conductor trace 21 is secured by the remaining via 26. In particular, because the ceramic substrate 10 and the resin layer 20A formed of different materials have different coefficients of thermal expansion, gaps SP are likely to be formed between some vias 24 and 25 and the first conductor trace 11 as shown in FIG. 2(b). Since the plurality of vias 24 to 26 are present, it is possible to effectively increase the probability of securing the electrical conduction between the first conductor trace 11 and the second conductor trace 21, thereby suppressing occurrence of a connection failure.

In addition, in the present embodiment, the first conductor trace 11 and the second conductor trace 21 are connected by the three vias 24 to 26. In the present embodiment, since the three vias 24 to 26 (i.e., many vias) are provided, the area of joining between the first conductor trace 11 and the three vias 24 to 26 and the area of joining between the second conductor trace 21 and the three vias 24 to 26 increase. Therefore, occurrence of a connection failure between the first conductor trace 11 and the second conductor trace 21 is suppressed further.

### SECOND EMBODIMENT

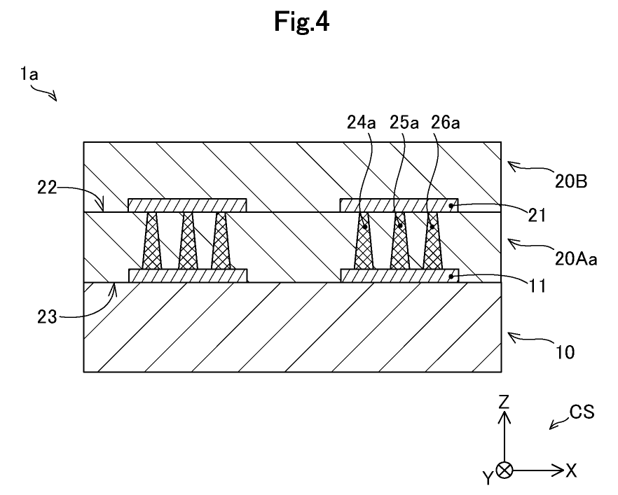

FIG. 4 is a schematic sectional view of a wiring substrate 1a of a second embodiment. The wiring substrate 1a of the second embodiment differs from the wiring substrate 1 of the first embodiment in that vias 24a to 26a penetrating a resin layer 20Aa have a shape different from that of the vias 24 to 26 in the first embodiment. Therefore, in the second embodiment, the shape of the vias 24a to 26a will be described, and structural portions identical to those of the first embodiment will not be described.

As shown in FIG. 4, the vias 24a to 26a are formed in such a manner that a cross-sectional area of each via perpendicular to the stacking direction gradually increases in the resin layer 20Aa from one main face 22 toward the other main face 23. Therefore, in the second embodiment, a sum of the areas of joining between the three vias 24a to 26a and the first conductor trace 11 is larger than a sum of the areas of joining between the three vias 24a to 26a and the second conductor trace 21. By virtue of this, it is possible to further suppress occurrence of a joining failure between the first conductor trace 11 and the vias 24a to 26a, which joining failure is more likely to occur as compared with a joining failure between the second conductor trace 21 and the vias 24a to 26a.

### MODIFICATIONS OF THE PRESENT EMBODIMENT

The present invention is not limited to the above-described embodiment and can be practiced in various forms without departing from the gist of the invention. For example, the following modifications are possible.

The above-described wiring substrates 1 and 1a of the first and second embodiments are mere examples, and the wiring substrates 1 and 1a may be modified, so long as a plurality of vias for establishing connection between the first conductor trace 11 and the second conductor trace 21 are formed to penetrate the resin layer 20A or 20Aa. The materials used for forming the ceramic substrate 10, the resin layers 20A, 20Aa, and 20B, the first conductor trace 11, the second conductor trace 21, and the vias 24 to 26 and 24a to 26a can be changed within the known range. The plurality of vias for establishing connection between the first conductor trace and the second conductor trace encompass a mode in which a plurality of vias are formed to establish connection between the first conductor trace and the second conductor trance, but, because of a joining failure, only one via establishes connection between the first conductor trace and the second conductor trace.

The number of vias for establishing connection between the first conductor trace 11 and the second conductor trace 21 may be two or four or more. The plurality of vias may have different shapes, and the cross section of each via is not required to be circular and have a diameter of 30 micrometers. For example, the plurality of vias may have different cross-sectional areas and different cross-sectional shapes. The layout of the plurality of vias may be modified within the range of known techniques. For example, in the case where the first conductor trace 11 has a square shape as viewed in the stacking direction, the three vias may be formed in such a manner that the centroids of the three vias are respectively located at the positions of the vertices of an equilateral triangle. In addition, the plurality of vias may be disposed in such a manner that the centroid of a polygon formed by connecting the plurality of vias coincides with the centroids of the first conductor trace 11 or the second conductor trace 21.

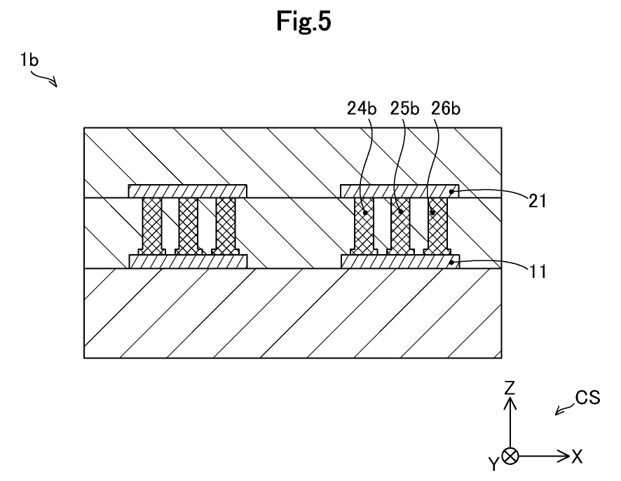

FIG. 5 is a schematic sectional view of a wiring substrate 1b of a modification. In the wiring substrate 1bshown in FIG. 5, vias 24bto 26bare formed in such a manner that a cross-sectional areas of the vias 24b to 26b at their ends connected to the first conductor trace 11 are larger than those of the vias 24 to 26 of the wiring substrate 1 of the first embodiment shown in FIG. 1. As shown in this modification, it is possible to modify the shape of the vias that makes a sum of the areas of joining between the vias 24bto 26b and the first conductor trace 11 larger than a sum of the areas of joining between the vias 24b to 26b and the second conductor trace 21.

Although the present invention has been described on the basis of its embodiment and modifications, the above-described embodiment is provided so as to facilitate the understanding of the present invention and does not limit the present invention. The present invention can be changed or improved without departing from the purpose and the scope of the claims, and encompasses equivalents thereof. Also, the technical feature(s) may be eliminated unless the present specification mentions that the technical feature(s) is essential.

The present invention can be realized as the following modes.

### APPLICATION EXAMPLE 1

A wiring substrate comprising:

a ceramic substrate having first and second main faces and having a first conductor trace formed on its first main face; and

a resin layer having first and second main faces and stacked on the first main face of the ceramic substrate, on which the first conductor trace is formed, the resin layer having a second conductor trace formed on its second main face, different from its first main face facing the ceramic substrate, wherein

the resin layer has a plurality of vias which have electrical conductivity and establish connection between the first conductor trace and the second conductor trace, the vias penetrating the resin layer in a stacking direction in which the ceramic substrate and the resin layer are stacked.

### APPLICATION EXAMPLE 2

The wiring substrate described in the application example 1, wherein a number of the vias for establishing connection between the first conductor trace and the second conductor trace is three or more.

### APPLICATION EXAMPLE 3

The wiring substrate described in the application example 1 or 2, wherein a sum of areas of joining between the plurality of vias and the first conductor trace is larger than a sum of areas of joining between the plurality of vias and the second conductor trace.

What is claimed is:

1. A wiring substrate comprising:
a ceramic substrate having first and second main faces and having a first conductor trace formed on its first main face; and
a resin layer having first and second main faces and stacked on the first main face of the ceramic substrate, on which the first conductor trace is formed, the resin layer having a second conductor trace formed on its second main face, different from its first main face facing the ceramic substrate, wherein
the resin layer has a plurality of vias which have electrical conductivity and establish connection between the first conductor trace and the second conductor trace, the vias penetrating the resin layer in a stacking direction in which the ceramic substrate and the resin layer are stacked.

2. The wiring substrate according to claim 1, wherein a number of the vias for establishing connection between the first conductor trace and the second conductor trace is three or more.

3. The wiring substrate according to claim 1, wherein a sum of areas of joining between the plurality of vias and the first conductor trace is larger than a sum of areas of joining between the plurality of vias and the second conductor trace.

4. The wiring substrate according to claim 2, wherein a sum of areas of joining between the plurality of vias and the first conductor trace is larger than a sum of areas of joining between the plurality of vias and the second conductor trace.
